(19) United States
(12) Patent Application Publication
(10) Pub. No.: US 2026/0033214 A1
(43) Pub. Date: Jan. 29, 2026

(54) DISPLAY PANEL AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yanwei LU, Beijing (CN); Zhuoran YAN, Beijing (CN); Fengli JI, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/996,796

(22) PCT Filed: Feb. 19, 2024
(86) PCT No.: PCT/CN2024/077592

§ 371 Date: Jan. 17, 2025

(30) Foreign Application Priority Data
Feb. 27, 2023 (CN) 202310171507.2

(51) Int. Cl. H10K 59/80; H10K 59/131

(52) U.S. Cl. CPC H10K 59/873; H10K 59/131

(57) ABSTRACT

A display panel includes a display substrate, where the display substrate includes a display area and a peripheral area; a plurality of light-emitting elements; an encapsulation cover plate, provided at a side of the light-emitting elements away from the display substrate; and an encapsulation structure, provided on a surface of the display substrate at a side of the peripheral area, where the encapsulation structure is located between the display substrate and is provided with a smooth curved section. A section of the display substrate covered by the encapsulation structure includes a base, an electrically conductive layer and an insulating layer stacked in sequence. The electrically conductive layer is provided with a plurality of first openings. The insulating layer fills the first opening. The insulating layer is provided with at least one second opening in a region where the first opening is located. The encapsulation structure fills the second opening.

### CROSS-REFERENCE TO RELATED APPLICATIONS

The present disclosure is the U.S. National Stage of International Application No. PCT/CN2024/077592, filed on Feb. 19, 2024, which claims the priority to the Chinese Patent Application No. 202310171507.2, entitled “DISPLAY PANEL AND DISPLAY DEVICE”, filed on Feb. 27, 2023, and the entire contents of both of which are incorporated herein by reference for all purposes.

### TECHNICAL FIELD

The present disclosure relates to the field of display technologies, and specifically to a display panel and a display device.

### BACKGROUND

This part is intended to provide background or context for the embodiments stated in the claims. The descriptions herein are not recognized as prior art by virtue of their inclusion in this part.

Organic light-emitting diode display panels and quantum dot light-emitting diode display panels and the like are often encapsulated by using an encapsulation adhesive as an encapsulation structure. The encapsulation structure is located outside and around the display area (AA area), and is configured to block water vapor from entering the display panel.

### SUMMARY

The present disclosure provides a display panel and a display device.

The present disclosure adopts the following technical solutions. A display panel,

including:
a display substrate, where the display substrate includes a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, where the encapsulation structure is located between the display substrate and the encapsulation cover plate and surrounds the plurality of light-emitting elements, and the encapsulation structure is provided with a smooth curved section; where
a section of the display substrate covered by the encapsulation structure includes a base, an electrically conductive layer and an insulating layer stacked in sequence along a direction pointed from the display substrate towards the encapsulation cover plate, the electrically conductive layer is provided with a plurality of first openings, the insulating layer fills the first opening, the insulating layer is provided with at least one second opening in a region where the first opening is located, and the encapsulation structure fills the second opening; and
at at least part of the smooth curved section of the encapsulation structure, the first openings are arranged in a plurality of queues along an orientation of the at least part of the smooth curved section, a center distance between two adjacent first openings in each of the queues is substantially equal, and the center distance between the two adjacent first openings in any one of the queues is substantially equal to the center distance between the two adjacent first openings in another one of the queues.

In some embodiments, at the at least part of the smooth curved section of the encapsulation structure, the first openings are substantially aligned along a normal direction of the encapsulation structure.

In some embodiments, at the at least part of the smooth curved section of the encapsulation structure, the first openings are staggered along a normal direction of the encapsulation structure.

In some embodiments, at the at least part of the smooth curved section of the encapsulation structure, the plurality of queues are numbered in sequence according to the normal direction of the at least part of the smooth curved section, first openings in odd-numbered ones of the queues are substantially aligned along the normal direction of the encapsulation structure, first openings in even-numbered ones of the queues are substantially aligned along the normal direction of the encapsulation structure, and the first openings in the odd-numbered ones of the queues are staggered, along the normal direction of the encapsulation structure, with the first openings in the even-numbered ones of the queues; or
at the at least part of the smooth curved section of the encapsulation structure, first openings in any two of the queues are staggered along the normal direction of the at least part of the smooth curved section.

In some embodiments, in the same queue of the plurality of queues, a standard deviation of the center distance between the adjacent first openings is within 10%; and a standard deviation of the center distance between the two adjacent first openings in any one of the queues and the center distance between the two adjacent first openings in another one of the queues is within 10%.

In some embodiments, the first opening is formed in a shape of a rectangle, a circle, or a regular polygon.

In some embodiments, the second opening is formed in a shape of a rectangle, a circle, or a regular polygon.

In some embodiments, the display panel includes at least part of an arc edge, and the orientation of the at least part of the smooth curved section of the encapsulation structure is parallel to an orientation of the at least part of the arc edge of the display panel.

In some embodiments, the light-emitting element includes an organic light-emitting diode or a quantum dot light-emitting diode.

In some embodiments, a number of the second opening is multiple, and a gap is provided between the second opening and the first opening where the second opening is located.

In some embodiments, a number of the second opening is one, and the first opening coincides with the second opening where the first opening is located.

In some embodiments, a distance between each of first openings in the same queue and an outer edge of the encapsulation structure is equal.

In some embodiments, a number of edges of the regular polygon is not less than four.

In some embodiments, a material of the electrically conductive layer is molybdenum.

The present disclosure adopts the following technical solutions. A display panel, including:
a display substrate, including a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, where the encapsulation structure is located between the display substrate and the encapsulation cover plate, and surrounds the plurality of light-emitting elements; where
the display substrate is provided with a plurality of grooves, in a region covered by the encapsulation structure, on a surface of the display substrate at a side of the display substrate facing the encapsulation cover plate; and the encapsulation structure fills the plurality of grooves;
the display substrate further includes a plurality of exposed electrical test pads, a test line electrically connected to the electrical test pad, and an electrostatic protection circuit electrically connected to the test line; and
the electrostatic protection circuit is connected to a second wiring located in a second wiring layer; at least a partial section of the test line is located in a first wiring layer; the first wiring layer and the second wiring layer are separated from each other by an insulating material; the second wiring and a first wiring are electrically connected, through a via passing through the insulating material, to each other at an overlapping position of the second wiring and the first wiring; and at least an orthogonal projection, on a plane where the display substrate is located, of the via connecting the first wiring and the second wiring is located within an orthogonal projection, on the plane where the display substrate is located, of the encapsulation structure.

In some embodiments, the electrostatic protection circuit and the electrical test pads are located at a side of the encapsulation structure away from the display area.

In some embodiments, an orthogonal projection, on the plane where the display substrate is located, of the electrostatic protection circuit, and the orthogonal projection, on the plane where the display substrate is located, of the via connecting the first wiring and the second wiring are located within the orthogonal projection, on the plane where the display substrate is located, of the encapsulation structure.

In some embodiments, the orthogonal projection, on the plane where the display substrate is located, of the via connecting the first wiring and the second wiring is located within the orthogonal projection, on the plane where the display substrate is located, of the encapsulation structure.

The present disclosure adopts the following technical solutions. A display panel, including:
a display substrate, including a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, where the encapsulation structure is located between the display substrate and the encapsulation cover plate and surrounds the plurality of light-emitting elements, and the encapsulation structure is provided with a smooth curved section; where
the display substrate is provided with a plurality of grooves, in a region covered by the encapsulation structure, on a surface of the display substrate at a side of the display substrate facing the encapsulation cover plate; and the encapsulation structure fills the plurality of grooves; and
at a position where at least part of the smooth curved section of the encapsulation structure is located, the grooves are gathered into a plurality of groove clusters, the plurality of groove clusters are arranged in a plurality of queues along an orientation of the at least part of the smooth curved section, a center distance between two adjacent groove clusters in a same queue is substantially equal, and the center distance between the two adjacent groove clusters in any one of the queues is substantially equal to the center distance between the two adjacent groove clusters in another one of the queues.

In some embodiments, at the at least part of the smooth curved section of the encapsulation structure, the groove clusters are substantially aligned along a normal direction of the encapsulation structure.

In some embodiments, at the at least part of the smooth curved section of the encapsulation structure, the groove clusters are staggered along a normal direction of the encapsulation structure.

In some embodiments, at the at least part of the smooth curved section of the encapsulation structure, the plurality of queues are numbered in sequence according to the normal direction of the at least part of the smooth curved section, groove clusters in odd-numbered ones of the queues are substantially aligned along the normal direction of the encapsulation structure, groove clusters in even-numbered ones of the queues are substantially aligned along the normal direction of the encapsulation structure, and the groove clusters in the odd-numbered ones of the queues are staggered, along the normal direction of the encapsulation structure, with the groove clusters in the even-numbered ones of the queues; or
at the at least part of the smooth curved section of the encapsulation structure, groove clusters in any two of the queues are staggered along the normal direction of the at least part of the smooth curved section.

In some embodiments, in the same queue of the plurality of queues, a standard deviation of a distance between geometric centers of the adjacent groove clusters is within 10%; and a standard deviation of the distance between the geometric centers of the adjacent groove clusters in any one of the queues and the distance between the geometric centers of the adjacent groove clusters in another one of the queues is within 10%.

In some embodiments, an opening of the groove is formed in a shape of a rectangle, a circle, or a regular polygon.

In some embodiments, the groove is formed by an insulating material in a surrounding manner.

In some embodiments, the display substrate includes an electrically conductive layer, the electrically conductive layer is provided with a plurality of opening regions, the insulating material fills the opening region of the electrically conductive layer, the groove clusters are provided in one-to-one correspondence with the opening regions of the electrically conductive layer, and the groove in the groove cluster extends into a corresponding one of the opening regions of the electrically conductive layer.

The present disclosure adopts the following technical solutions. A display panel, including:
a display substrate, including a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, where the encapsulation structure is located between the display substrate and the encapsulation cover plate, and surrounds the plurality of light-emitting elements; wherein
a section of the display substrate covered by the encapsulation structure includes a base, an electrically conductive layer and an insulating layer stacked in sequence along a direction pointed from the display substrate towards the encapsulation cover plate, the electrically conductive layer is provided with a plurality of first openings, the insulating layer fills the first opening, the insulating layer is provided with at least one second opening in a region where the first opening is located, a gap is provided between the second opening and the first opening where the second opening is located, and the encapsulation structure fills the second opening; and
at any position of a boundary of an orthogonal projection of at least one of the first openings on a reference plane, an angle between a left tangent line and a right tangent line is greater than 90°, and/or at any position of a boundary of an orthogonal projection of at least one second opening on the reference plane, an angle between a left tangent line and a right tangent line is greater than 90°; and the reference plane is a plane where the display substrate is located.

In some embodiments, at least one of the first openings is in a shape of a polygon, and vertex angles of the polygon are all obtuse angles; and/or at least one of the first openings is in a shape of a polygon with vertex angles chamfered to round corners; and/or at least one of the first openings is in a shape of a closed smooth curve.

In some embodiments, at least one second opening is in a shape of a polygon, and vertex angles of the polygon are all obtuse angles; and/or at least one second opening is in a shape of a polygon with vertex angles chamfered to round corners; and/or at least one second opening is in a shape of a closed smooth curve.

The present disclosure adopts the following technical solutions. A display panel, including:
a display substrate, including a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, where the encapsulation structure is located between the display substrate and the encapsulation cover plate, and surrounds the plurality of light-emitting elements; where
the display substrate is provided with a plurality of grooves, in a region covered by the encapsulation structure, on a surface of the display substrate at a side of the display substrate facing the encapsulation cover plate; and the encapsulation structure fills the plurality of grooves; and
at any position of a boundary of an orthogonal projection of at least one of the grooves on a reference plane, an angle between a left tangent line and a right tangent line is greater than 90°, and the reference plane is a plane where the display substrate is located.

In some embodiments, an opening of at least one of the grooves is in a shape of a polygon, and vertex angles of the polygon are all obtuse angles; and/or an opening of at least one of the grooves is in a shape of a polygon with vertex angles chamfered to round corners; and/or an opening of at least one of the grooves is in a shape of a closed smooth curve.

In some embodiments, the groove is formed by an insulating material in a surrounding manner.

In some embodiments, the display substrate includes an electrically conductive layer, the electrically conductive layer is provided with a plurality of opening regions, the insulating material fills the opening region of the electrically conductive layer, the grooves are gathered into a plurality of groove clusters, the groove clusters are provided in one-to-one correspondence with the opening regions of the electrically conductive layer, and the groove in the groove cluster extends into a corresponding one of the opening regions of the electrically conductive layer.

In some embodiments, at any position of a boundary of an orthogonal projection of at least one of the opening regions on the reference plane, an angle between a left tangent line and a right tangent line is greater than 90°.

In some embodiments, at least one of the opening regions is in a shape of a polygon, and vertex angles of the polygon are all obtuse angles; and/or at least one of the opening regions is in a shape of a polygon with vertex angles chamfered to round corners; and/or at least one of the opening regions is in a shape of a closed smooth curve.

The present disclosure adopts the following technical solutions. A display device, including the display panel described above.

### BRIEF DESCRIPTION OF THE DRAWINGS

FIG. 1 is a cross-sectional view of a display panel of an embodiment of the present disclosure.

FIG. 2 is an orthogonal projection view of a partial structure of a display panel of an embodiment of the present disclosure.

FIG. 3 is a cross-sectional view of the display substrate in FIG. 1.

FIG. 4a is a layout diagram of a display substrate in a display panel of an embodiment of the present disclosure.

FIG. 4b is a partially enlarged view of the layout diagram shown in FIG. 4a.

FIG. 4c is a partially enlarged view of the layout diagram shown in FIG. 4a.

FIG. 4d is a circuit diagram of a single shift register unit in the layout diagram shown in FIG. 4c.

FIG. 5 is a layout diagram of a display substrate in a display panel of some other embodiments of the present disclosure.

FIG. 6 is a layout diagram of a display substrate in a display panel of some other embodiments of the present disclosure.

FIG. 7a is a layout diagram of a display substrate in a display panel of some other embodiments of the present disclosure.

FIG. 7b is a partially enlarged view of the electrostatic protection circuit in the layout diagram shown in FIG. 7a.

FIG. 7c is a schematic diagram of the electrostatic protection circuit of the display substrate shown in FIG. 7a.

FIG. 7d is a partially enlarged view of the peripheral area in the layout diagram shown in FIG. 7a.

FIG. 7e is an equivalent circuit diagram of a local circuit in the layout diagram shown in FIG. 7d.

FIG. 8 is a schematic diagram of a structure of a display device of an embodiment of the present disclosure.

FIG. 9 is a schematic diagram of an overall structure of a display substrate of an embodiment of the present disclosure.

FIG. 10 is a partial layout diagram of a display substrate of an embodiment of the present disclosure.

FIG. 11 is a partial layout diagram of a display substrate of another embodiment of the present disclosure.

FIG. 12 is a partial layout diagram of a display substrate of another embodiment of the present disclosure.

Reference numerals: 1, display substrate; 2, encapsulation cover plate; 3, encapsulation structure; 4, support column; 5, light-emitting element array; H1, first opening; H2, second opening; 10, base; 11, buffer layer; 12, insulating layer; 13, electrically conductive layer; 1a, display area; 1b, peripheral area; 1e, electrostatic protection circuit; L1, first wiring; L2, second wiring; 100, polarizer; 200, protection cover plate; L, normal direction; 1f, groove; 1g, groove cluster; 6, outer edge of encapsulation structure.

### DETAILED DESCRIPTION

The present disclosure is further described below in connection with the embodiments shown in the accompanying drawings.

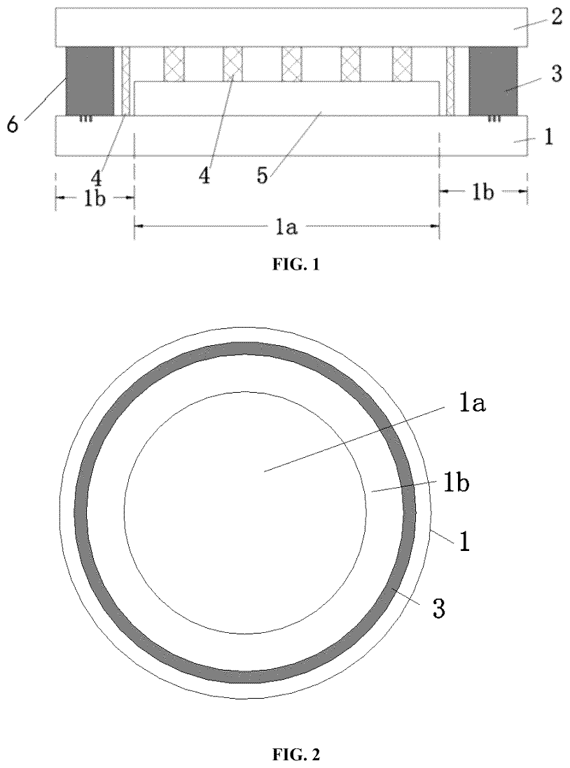

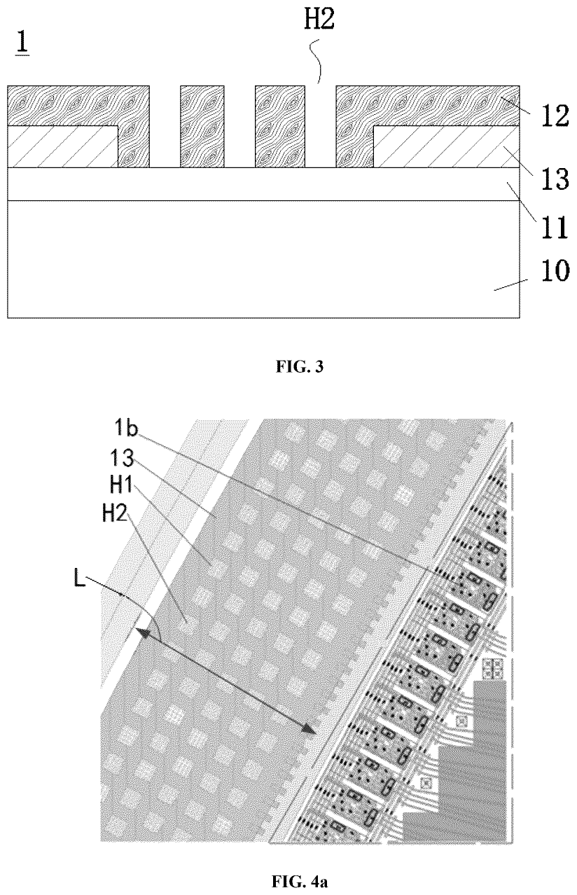

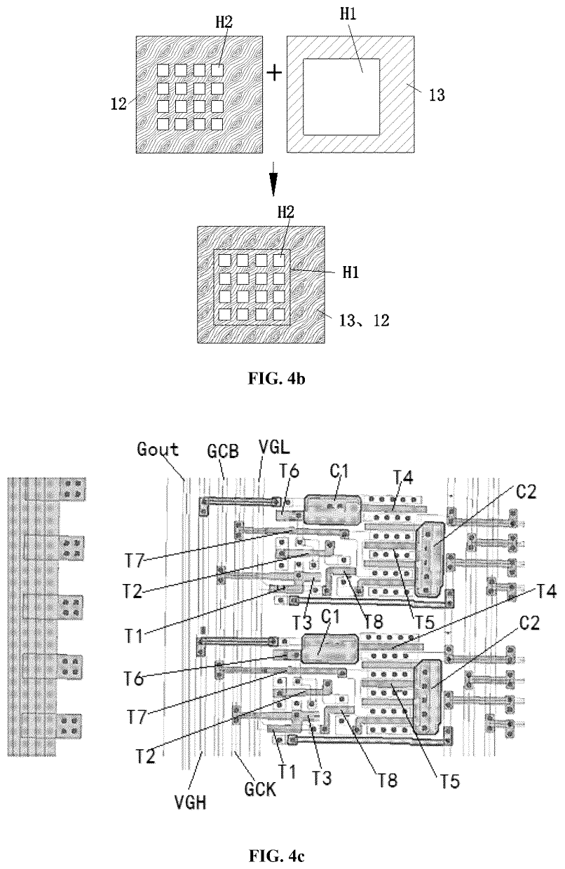

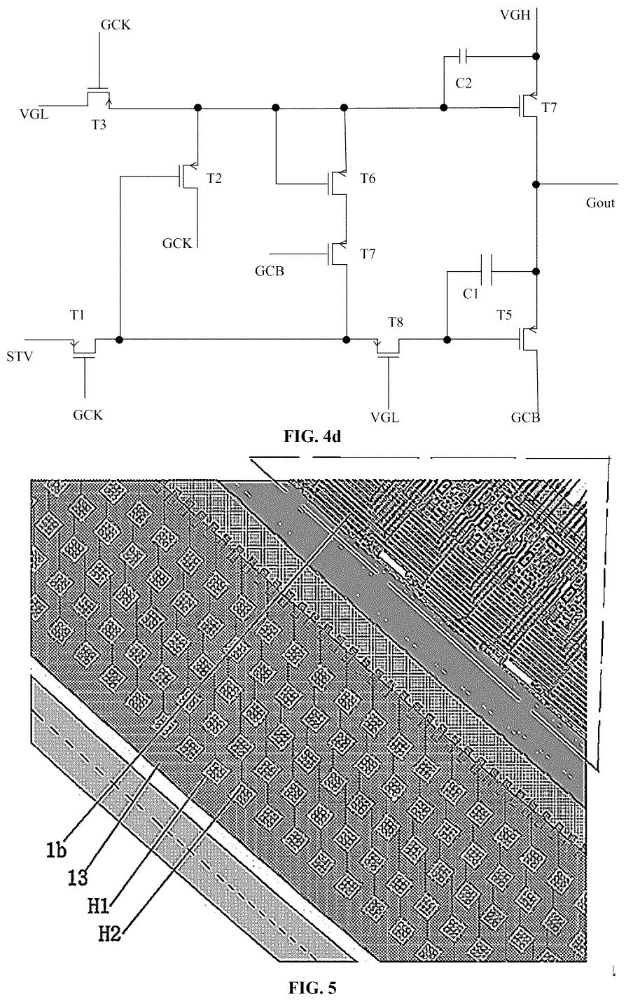

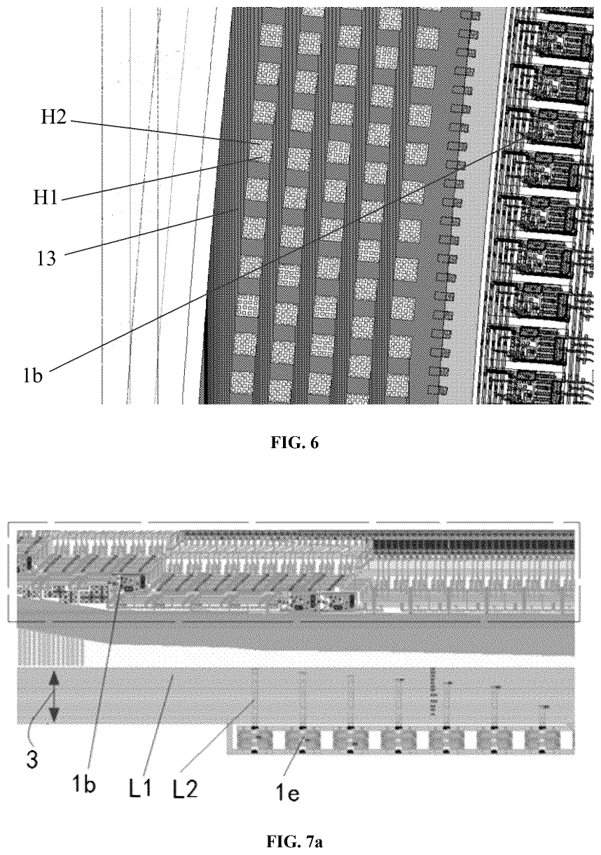

FIG. 1 is a cross-sectional view of a display panel of an embodiment of the present disclosure. FIG. 2 is an orthogonal projection view of a partial structure of a display panel of an embodiment of the present disclosure. FIG. 3 is a cross-sectional view of the display substrate in FIG. 1. FIG. 4a is a layout diagram of a display substrate in a display panel of an embodiment of the present disclosure. FIG. 4b is a partially enlarged view of the layout diagram shown in FIG. 4a. FIG. 4c is a partially enlarged view of the layout diagram shown in FIG. 4a. FIG. 4d is a circuit diagram of a single shift register unit in the layout diagram shown in FIG. 4c. FIG. 5 is a layout diagram of a display substrate in a display panel of some other embodiments of the present disclosure. FIG. 6 is a layout diagram of a display substrate in a display panel of some other embodiments of the present disclosure.

Referring to FIGS. 1 to 4d, the embodiments of the present disclosure provide a display panel, including:
a display substrate 1, where the display substrate 1 includes a display area 1a and a peripheral area 1b;
a plurality of light-emitting elements (the plurality of light-emitting elements form a light-emitting element array 5), provided on a surface of the display substrate 1 at a side of the display area 1a;
an encapsulation cover plate 2, provided at a side of the light-emitting elements away from the display substrate 1; and
an encapsulation structure 3, provided on a surface of the display substrate 1 at a side of the peripheral area 1b, where the encapsulation structure 3 is located between the display substrate 1 and the encapsulation cover plate 2 and surrounds the plurality of light-emitting elements, and the encapsulation structure 3 is provided with a smooth curved section.

The plurality of light-emitting elements are located in a region where the display area 1a (AA area) of the display substrate 1 is located. The present disclosure does not specifically limit the shape of the light-emitting elements and their arrangement.

The peripheral area 1b of the display substrate 1 surrounds the display area 1a. For example, a gate driving circuit (GOA) may be provided in the peripheral area 1b of the display substrate 1.

The encapsulation structure 3 is tightly bonded to the encapsulation cover plate 2 and the display substrate 1. The encapsulation structure 3 can support the encapsulation cover plate 2 on the one hand, and can block water vapor from entering the interior of the display panel on the other hand.

Specifically, in combination with FIG. 1, a plurality of grooves (not labelled) are provided on a surface of the display substrate 1 at a side of the display substrate 1 facing the encapsulation cover plate 2, and the encapsulation structure 3 fills these grooves. This increases the contact area between the encapsulation structure 3 and the display substrate 1, improves the encapsulation capability, and enhances the solidity of the position of the encapsulation structure 3, achieving a good water vapor blocking effect.

Specifically, referring to FIGS. 3 and 4, a section of the display substrate 1 covered by the encapsulation structure 3 includes a base 10, an electrically conductive layer 13 and an insulating layer 12 that are stacked in sequence along a direction pointed from the display substrate 1 towards the encapsulation cover plate 2. The electrically conductive layer 13 is provided with a plurality of first openings H1. The insulating layer 12 fills the first opening H1. The insulating layer 12 is provided with at least one second opening H2 in a region where the first opening H1 is located. The encapsulation structure 3 fills the second opening H2. The opening of the first opening H1 and the opening of the second opening H2 are both rectangular in shape.

In some embodiments, the number of the second opening H2 may be one, and the second opening H2 coincides with the first opening H1 where the second opening H2 is located. In this way, the contact area between the encapsulation structure 3 and the display substrate 1 can be increased, the encapsulation capability can be improved, and the solidity of the position of the encapsulation structure 3 is enhanced, achieving a good water vapor blocking effect.

In some embodiments, the number of second openings H2 may also be more than one, and a gap may be provided between the second opening H2 and the first opening H1 where the second opening H2 is located. In this way, by nesting the first opening H1 and the second opening H2, the contact area of the encapsulation structure 3 can be greatly increased, which increases the encapsulation capability and achieves a good water oxygen blocking and sealing effect.

Specifically, the electrically conductive layer 13 is provided on a buffer layer 11, and the buffer layer 11 is provided on the base 10. The second opening H2 of the insulating layer 12 exposes the buffer layer 11 on the base 10.

Specifically, the buffer layer 11 may be made of an inorganic material such as silicon oxide, silicon nitride, etc., achieving the effect of blocking water oxygen and blocking alkaline ions.

Specifically, the base 10 is a rigid base. For example, the material of the base 10 may be glass.

Both the display substrate 1 and the encapsulation cover plate 2 are rigid structures. In some embodiments, the material of the encapsulation cover plate 2 is glass. In some embodiments, some functional circuits (e.g., touch control circuits) may also be provided on the encapsulation cover plate 2. In other embodiments, no functional circuits are provided on the encapsulation cover plate 2.

The light-emitting element is, for example, an organic light-emitting diode or a quantum dot light-emitting diode. In some embodiments, the encapsulation structure 3 is obtained by processing an encapsulation adhesive. The material of the encapsulation adhesive includes a glass material and an organic solvent. The glass material is, for example, borosilicate glass.

In some embodiments, distances between first openings H1 in a same queue and an outer edge 6 of the encapsulation structure may be equal, i.e., in the same queue, the line connecting the centers of the first openings H1 may be parallel to the outer edge 6 of the encapsulation structure. In this way, as many first openings H1 as possible can be provided in the limited space of the narrow bezel. As a result, the density of the first openings H1 at all positions remains consistent, achieving uniformity of the encapsulation. At the same time, the encapsulation will not fail at individual positions, and water vapor can be effectively isolated. This advantage is even more obvious especially in the case of an extremely narrow bezel.

Specifically, a support column 4 supports the encapsulation cover plate 2. The material of the support column 4 includes, for example, polyimide.

Specifically, in preparing the display panel, an encapsulation adhesive is coated on an encapsulation region of the display substrate 1, and the organic solvent is removed from the encapsulation adhesive by heating the encapsulation adhesive. Subsequently, the display substrate 1 is attached to the encapsulation cover plate 2, and the encapsulation adhesive with the organic solvent removed is irradiated by using the laser to form a sealed space between the display substrate 1 and the encapsulation cover plate 2.

In some embodiments, the display panel is in a shape of a circle, an ellipse, or a closed smooth curve of other shape. In other embodiments, the display panel is in a shape of a polygon with tips chamfered to rounded corners. An orientation of the encapsulation structure 3 is substantially the same as an orientation of a boundary of the display panel. An orthographic projection of the encapsulation structure 3 on a plane where the display substrate 1 is located is, for example, in a shape of an annulus ring, an elliptical ring, or a closed ring of other shape. A center line of the closed ring is a closed smooth curve. A smooth curve means that the derivative function of the curve is continuous.

In some embodiments, the display panel includes at least part of an arc edge, and the orientation of at least part of the smooth curved section of the encapsulation structure 3 is parallel to an orientation of the at least part of the arc edge of the display panel.

FIGS. 4a, 5 and 6 show localized boundary regions of the display panel. It should be noted that FIGS. 4a, 5 and 6 are partially enlarged views, and the boundary of the display panel is a smooth curve.

A section of the display substrate 1 covered by the encapsulation structure 3 includes a base 10, an electrically conductive layer 13 and an insulating layer 12 that are stacked in sequence along a direction pointed from the display substrate 1 towards the encapsulation cover plate 2. The electrically conductive layer 13 is provided with a plurality of first openings H1. The insulating layer 12 fills the first opening H1. The insulating layer 12 is provided with at least one second opening H2 in a region where the first opening H1 is located. A gap is provided between the second opening H2 and the first opening H1 where the second opening H2 is located. The encapsulation structure 3 fills the second opening H2.

Specifically, in some embodiments, a thin film transistor of a top gate type is provided in the display area 1a of the display substrate 1. A gate material of the thin film transistor is, for example, polycrystalline. In some regions of the display area 1a of the display substrate 1, the display substrate 1 includes, along the direction pointed from the display substrate 1 towards the encapsulation cover plate 2, a base 10, a buffer layer 11, a polycrystalline silicon active layer, a gate insulating layer (e.g., an oxide of silicon), a gate electrode, an interlayer dielectric layer (e.g., an oxide of silicon), a source-drain electrode, and a passivation layer (e.g., an oxide of silicon).

In some sections covered by the encapsulation structure 3, the electrically conductive layer 13 where the first opening H1 is located is provided in a same layer as the gate electrode. In some embodiments, a material of the electrically conductive layer 13 is molybdenum. Molybdenum has a high light reflectivity, and can improve the curing effect of the encapsulation structure 3.

The so-called “provided in a same layer” in the present disclosure refers to two structures formed by a same material layer, and does not define that the distances between the two and the base 10 are equal.

In other sections covered by the encapsulation structure 3, the electrically conductive layer 13 where the first opening H1 is located is provided in a same layer as the source-drain electrode of the thin film transistor. In some embodiments, the material of the source-drain electrode includes, for example, a multilayer metal of titanium-aluminum-titanium. In these sections, the electrically conductive layer 13 may be the topmost electrically conductive layer of a plurality of electrically conductive layers, and an insulating material layer is provided between the plurality of electrically conductive layers.

Some sections of the insulating layer 12 may be of a single layer structure, for example, these sections are provided in a same layer as the passivation layer. Other sections of the insulating layer 12 may be of a multi-layer structure, for example, these sections include a sub-layer provided in the same layer as the passivation layer, and a sub-layer provided in the same layer as the interlayer dielectric layer.

Specifically, the material of the insulating layer 12 includes an oxide of silicon, a nitride of silicon.

Specifically, the base 10 is, for example, a glass substrate.

Referring to FIGS. 4a, 5 and 6, at at least part of the smooth curved section of the encapsulation structure 3, the first openings H1 are arranged in a plurality of queues along an orientation of the at least part of the smooth curved section. A center distance between two adjacent first openings in a same queue is substantially equal. The center distance between two adjacent first openings in any one of the queues is substantially equal to the center distance between two adjacent first openings in another one of the queues.

Specifically, in the embodiments shown in FIGS. 4a, 5, and 6, at some sections covered by the encapsulation structure 3, the first openings H1 are arranged in five curved queues. Even if the width of the encapsulation structure 3 is further reduced, at at least part of the smooth curved section covered by the encapsulation structure 3, the first openings H1 may be relatively uniformly arranged in three curved queues, two curved queues, etc. The distribution of the first openings H1 is more uniform, the distribution of the second openings H2 is also more uniform, and the distribution of the grooves on the display substrate 1 accommodating the encapsulation structure 3 is more uniform, ensuring the solidity of the position of the encapsulation structure 3, and ensuring that the capability of the encapsulation structure 3 to block water vapor from entering the display panel is sufficiently reliable. Especially when the bezel size of the display panel is very small, the advantages of this design are more prominent.

In some embodiments, referring to FIG. 4a, at the at least part of the smooth curved section of the encapsulation structure 3, the first openings H1 are substantially aligned along a normal direction L of the encapsulation structure 3.

For example, in the five curved queues in which the first openings H1 are arranged in FIG. 4a, a normal of the encapsulation structure 3 passes through one first opening H1 in each of the queues.

In some embodiments, referring to FIGS. 5 and 6, at the at least part of the smooth curved section of the encapsulation structure 3, the first openings H1 are staggered along the normal direction L of the encapsulation structure 3. Such a design can increase the travel path of water vapor that invades the display panel, and the encapsulation structure 3 has a stronger capability to isolate the water vapor. At the same time, the number of first openings H1 placed in each column, although staggered, is the same, and good uniformity can also be achieved.

In some embodiments, referring to FIG. 5, at the at least part of the smooth curved section of the encapsulation structure 3, the plurality of queues are numbered in sequence according to the normal direction L of the at least part of the smooth curved section. First openings H1 in odd-numbered ones of the queues are substantially aligned along the normal direction L of the encapsulation structure 3. First openings H1 in even-numbered ones of the queues are substantially aligned along the normal direction L of the encapsulation structure 3. The first openings H1 in the odd-numbered ones of the queues are staggered, along the normal direction L of the encapsulation structure 3, with the first openings H1 in the even-numbered ones of the queues.

In other embodiments, referring to FIG. 6, at some smooth curved sections of the encapsulation structure 3, each first opening H1 is staggered, in the normal direction L of the smooth curved section, with first openings H1 in other queues. This further increases the path of water vapor for entering the interior of the display panel, and improves the water vapor blocking capability of the encapsulation structure 3.

In other embodiments, it is also possible that at part of the smooth curved section covered by the encapsulation structure 3, in a plurality of curved queues arranged by the first openings H1, first openings H1 of consecutive queues are substantially aligned along the normal direction L of the encapsulation structure 3, and first openings H1 of other consecutive queues are substantially aligned along the normal direction L of the encapsulation structure 3. These two portion of queues are staggered along the normal direction L of the encapsulation structure 3.

Two openings being substantially aligned along a particular normal direction L in the present disclosure means that the distances from the centers of the two openings to that normal are zero or sufficiently small, for example, the distance from the center of each of the openings to the normal is less than half of the size of the opening in the vertical line direction of the normal.

In some embodiments, in the same queue of the plurality of queues, a standard deviation of the center distance between adjacent first openings H1 is within 10%. A standard deviation of the center distance between two adjacent first openings H1 in any one of the queues and the center distance between two adjacent first openings H1 in another one of the queues is within 10%. That is, at at least part of the smooth curved section of the encapsulation structure 3, the first openings H1 in each of the queues are approximately distributed with equal spacings. The spacings between first openings H1 in respective ones of the queues are also approximately equal.

Specifically, the first openings H1 in the embodiments of the present disclosure have the same shape and size, and the second openings H2 have the same shape and size. However, the present disclosure does not specifically limit the shapes and sizes of the first openings H1 and the second openings H2.

In some embodiments, the first opening H1 is formed in a shape of a rectangle, a circle, or a regular polygon. The number of edges of the regular polygon is not less than four. In this way, the stress concentration in the drop test can be reduced, the passing rate of the drop test of the whole machine can be improved, and the drop-resistant performance of the display panel can be improved at the same time.

In some embodiments, the second opening H2 is formed in a shape of a rectangle, a circle, or a regular polygon. The number of edges of the regular polygon is not less than four. In this way, the stress concentration can be reduced, the passing rate of the drop test of the whole machine can be improved, and the drop-resistant performance of the display panel can be improved at the same time.

In some embodiments, the display panel is formed in a shape of a circle or a polygon with tips chamfered to rounded corners.

In some embodiments, the light-emitting element includes an organic light-emitting diode or a quantum dot light-emitting diode.

FIG. 4c shows two shift register units located in the peripheral area 1b and signal lines VGL, GCK, GCB, VGH, and Gout connected to the shift register units. FIG. 4d shows a circuit diagram of one of the shift register units.

Each of the shift register units includes transistors T1 to T7, and capacitors C1 and C2. In some embodiments, the signal line VGL provides a constant low level voltage, the signal line VGH provides a constant high level voltage, the signal lines GCK and GCB provide clock signals respectively, and the signal line Gout serves to transmit a cascade signal between different shift register units.

The transistor T1 receives an activating signal STV, for example, from an output end of a shift register unit of a previous stage. A connection node of the transistors T7 and T5 serves as an output node of the shift register unit.

The above is only an exemplary presentation of part of the circuit structure of the peripheral area 1b. The present disclosure does not limit the circuit design of the peripheral area 1b.

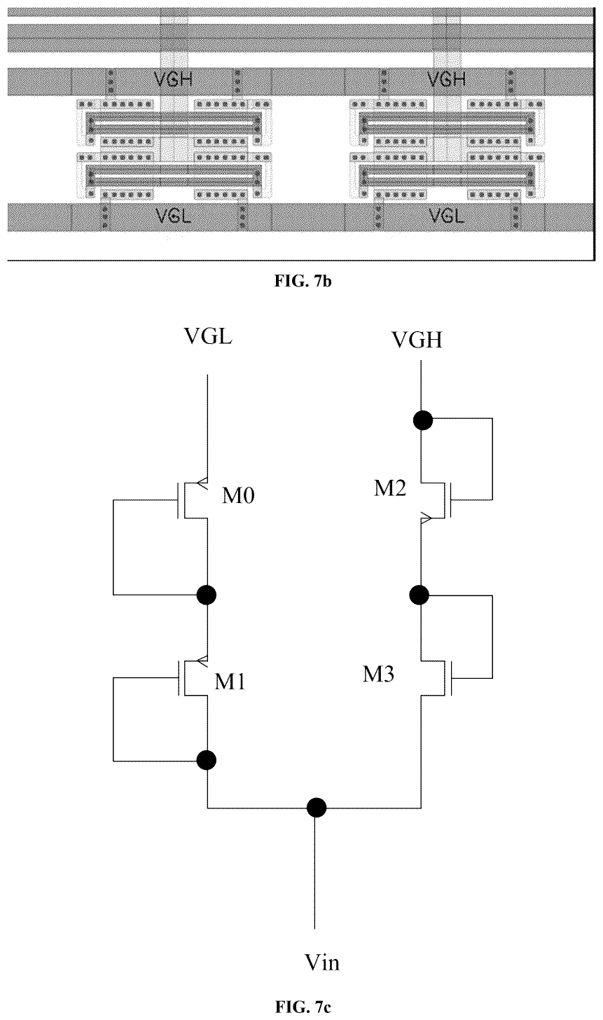

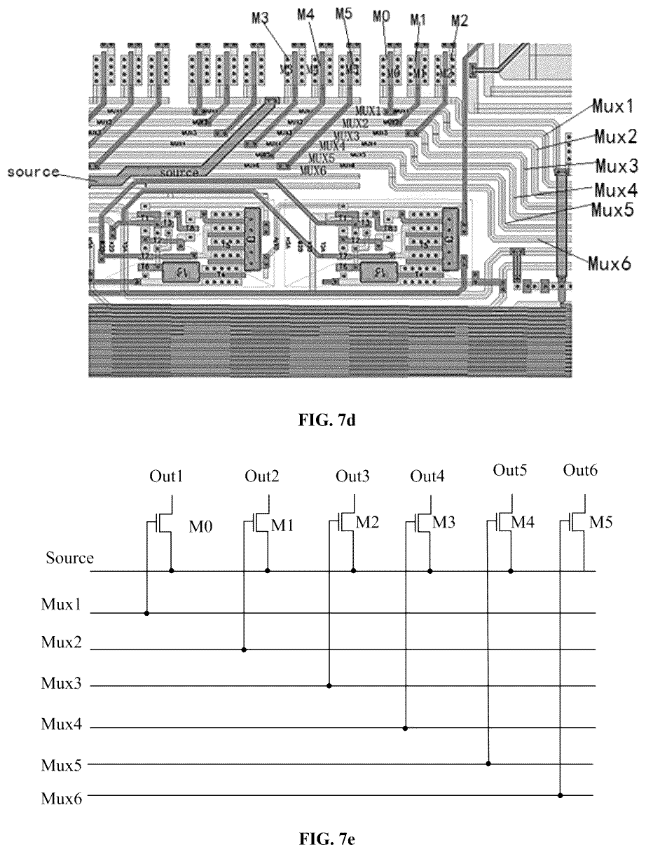

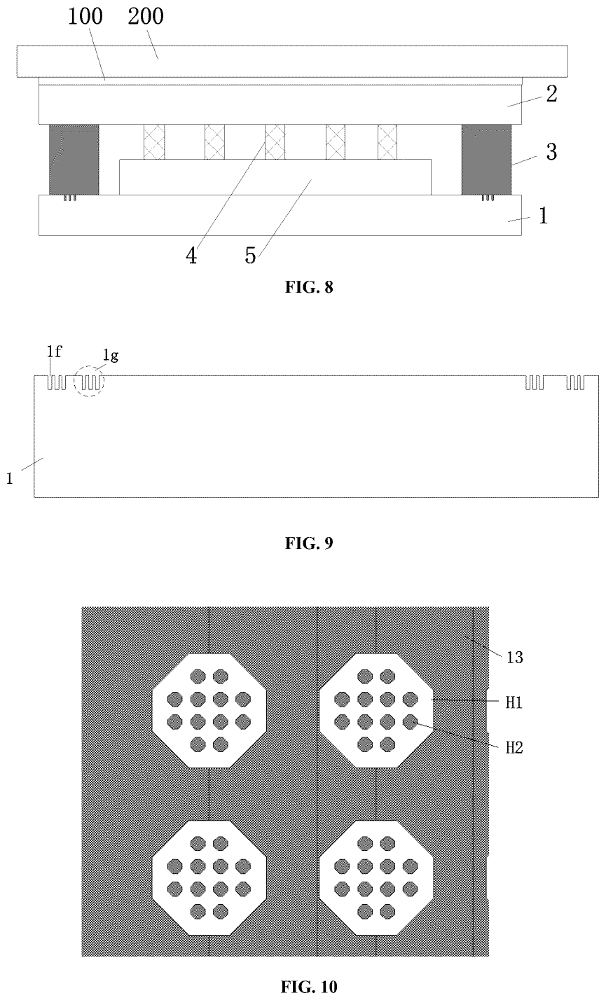

FIG. 7a is a layout diagram of a display substrate in a display panel of some other embodiments of the present disclosure. FIG. 7b is a partially enlarged view of the electrostatic protection circuit in the layout diagram shown in FIG. 7a. FIG. 7c is a schematic diagram of the electrostatic protection circuit of the display substrate shown in FIG. 7a. FIG. 7d is a partially enlarged view of the peripheral area in the layout diagram shown in FIG. 7a. FIG. 7e is an equivalent circuit diagram of a local circuit in the layout diagram shown in FIG. 7d. FIG. 8 is a schematic diagram of a structure of a display device of an embodiment of the present disclosure. FIG. 9 is a schematic diagram of an overall structure of a display substrate of an embodiment of the present disclosure.

Referring to FIGS. 7a to 7e and in combination with FIGS. 1, 2, 3, and 9, some embodiments of the present disclosure provide a display panel including: a display substrate 1, including a display area 1a and a peripheral area 1b; a plurality of light-emitting elements, provided on a surface of the display substrate 1 at a side of the display area 1a; an encapsulation cover plate 2, provided at a side of the light-emitting elements away from the display substrate 1; and an encapsulation structure 3, provided on a surface of the display substrate 1 at a side of the peripheral area 1b, where the encapsulation structure 3 is located between the display substrate 1 and the encapsulation cover plate 2, and surrounds the plurality of light-emitting elements. The display substrate 1 is provided with a plurality of grooves 1f, in a region covered by the encapsulation structure 3, on a surface of the display substrate 1 at a side of the display substrate 1 facing the encapsulation cover plate 2. The encapsulation structure 3 fills the plurality of grooves 1f.

Specifically, the position where the groove 1f is located is the position where the second opening H2 is located.

The display substrate 1 further includes a plurality of exposed electrical test pads, a test line electrically connected to the electrical test pad, and an electrostatic protection circuit le electrically connected to the test line.

The electrostatic protection circuit le is connected to a second wiring L2 located in a second wiring layer. At least a partial section of the test line is located in a first wiring layer. The first wiring layer and the second wiring layer are separated from each other by an insulating material. The second wiring L2 and a first wiring L1 are electrically connected, through a via passing through the insulating material, to each other at an overlapping position of the second wiring L2 and the first wiring L1. An orthogonal projection, on a plane where the display substrate 1 is located, of the via connecting the first wiring L1 and the second wiring L2 is located within an orthogonal projection, on the plane where the display substrate 1 is located, of the encapsulation structure 3.

The encapsulation structure 3 covers the via between the first wiring L1 and the second wiring L2. The encapsulation structure 3 can play a protection role for the via between the first wiring L1 and the second wiring L2. As a result, water vapor is effectively prevented from corroding the metal material where the via is located, and at the same time, there will not be a problem of trust corrosion, improving the passing rate of the drop test of the whole machine, and improving the drop-resistant performance of the display panel at the same time.

Further, the aforementioned first opening H1 may be provided in a region where the first wiring L1 is overlapped with the encapsulation structure 3, and the second opening H2 may be provided at a section where the insulating layer above the first wiring L1 covers the first opening H1. As a result, the second opening H2 accommodates the encapsulation structure 3.

It is also possible to provide the aforementioned first opening H1 in a region where the second wiring L2 is overlapped with the encapsulation structure 3, and provide the second opening H2 at a section where the insulating layer above the second wiring L2 covers the first opening H1. As a result, the second opening H2 accommodates the encapsulation structure 3.

Providing partial sections of the first wiring L1 and the second wiring L2 below the encapsulation structure 3 does not weaken the capability of the encapsulation structure 3 to block water vapor from entering the display panel. The first wiring L1 and the second wiring L2 may also be configured to form the groove 1f for accommodating the encapsulation structure 3, which can improve the passing rate of the drop test of the whole machine.

It should be noted that overlapping regions of the first wiring L1 and the second wiring L2 are generally provided with vias, and the aforementioned first opening H1 and second opening H2 are not provided in these regions.

It should be noted that the above design of the first wiring L1 and the second wiring L2 may be applied to display panels of any shape such as rectangular display panels, circular display panels, annular display panels, regular polygonal display panels and the like.

In some embodiments, the electrostatic protection circuit 1e and the electrical test pads are located at a side of the encapsulation structure 3 away from the display area 1a.

In some embodiments, an orthogonal projection, on the plane where the display substrate 1 is located, of the electrostatic protection circuit 1e, and the orthogonal projection, on the plane where the display substrate 1 is located, of the via connecting the first wiring L1 and the second wiring L2 are located within the orthogonal projection, on the plane where the display substrate 1 is located, of the encapsulation structure 3. In this way, the passing rate of the drop test of the whole machine can be improved, and the drop-resistant performance of the display panel can be improved at the same time.

Specifically, referring to FIGS. 7b and 7c, the electrostatic protection circuit le corresponding to each signal end Vin includes transistors M0 to M3. Transistors M0 and M1 are connected in series between the signal line VGL and the signal end Vin. Transistors M2 and M3 are connected in series between the signal line VGH and the signal end Vin. The signal end Vin is, for example, an electrical test pad. In a normal operating state, the gate electrode and the drain electrode of respective ones of transistors M0 to M3 are short-circuit connected.

The present disclosure does not limit the specific circuit structure of the electrostatic protection circuit 1e.

Specifically, FIG. 7d shows a circuit with two shift register units, and details of the circuit with two shift register units may be referred to FIGS. 4c and 4d. For example, each shift register unit includes transistors T1 to T8, and capacitors C1 and C2. A multiplexing circuit for the data line Source is also illustrated in FIG. 7d. In combination with FIG. 7d and FIG. 7e, the multiplexing control line Mux1 is connected to the control electrode of the transistor M0, and controls the on-off between the data line Source and the port Out1. The multiplexing control line Mux2 is connected to the control electrode of the transistor M1, and controls the on-off between the data line Source and the port Out2. The multiplexing control line Mux3 is connected to the control electrode of the transistor M2, and controls the on-off between the data line Source and the port Out3. The multiplexing control line Mux4 is connected to the control electrode of the transistor M3, and controls the on-off between the data line Source and the port Out4. The multiplexing control line Mux5 is connected to the control electrode of the transistor M4, and controls the on-off between the data line Source and the port Out5. The multiplexing control line Mux6 is connected to the control electrode of the transistor M5, and controls the on-off between the data line Source and the port Out6. Ports Out1 to Out16 are, for example, each connected to a row of pixel circuits. Thereby, one data line Source can drive six rows of pixel circuits in a time-division manner.

Based on the same inventive concept as the embodiments described above, with continued reference to FIGS. 4a, 5, and 6 and in combination with FIGS. 1, 2, 3, and 9, some embodiments of the present disclosure provide a display panel including: a display substrate 1, including a display area 1a and a peripheral area 1b; a plurality of light-emitting elements, provided on a surface of the display substrate 1 at a side of the display area 1a; an encapsulation cover plate 2, provided at a side of the light-emitting elements away from the display substrate 1; and an encapsulation structure 3, provided on a surface of the display substrate 1 at a side of the peripheral area 1b. The encapsulation structure 3 is located between the display substrate 1 and the encapsulation cover plate 2 and surrounds the plurality of light-emitting elements. The encapsulation structure 3 is provided with a smooth curved section. The display substrate 1 is provided with a plurality of grooves 1f, in a region covered by the encapsulation structure 3, on a surface of the display substrate 1 at a side of the display substrate 1 facing the encapsulation cover plate 2. The encapsulation structure 3 fills the plurality of grooves 1f.

At a position where at least part of the smooth curved section of the encapsulation structure 3 is located, the grooves 1f are gathered into a plurality of groove clusters 1g, the plurality of groove clusters 1g are arranged in a plurality of queues along an orientation of the at least part of the smooth curved section, a center distance between two adjacent groove clusters 1g in a same queue is substantially equal, and the center distance between two adjacent groove clusters 1g in any one of the queues is substantially equal to the center distance between two adjacent groove clusters 1g in another one of the queues.

Specifically, the second opening H2 forms the groove 1f on a surface of the display substrate 1. The grooves 1f located in the same first opening H1 form a groove cluster 1g.

As the density of the groove cluster 1g is more uniform and large enough, water vapor intrusion into the display panel can be effectively blocked.

In some embodiments, at the at least part of the smooth curved section of the encapsulation structure 3, the groove clusters 1g are substantially aligned along a normal direction L of the encapsulation structure 3.

In some embodiments, at the at least part of the smooth curved section of the encapsulation structure 3, the groove clusters 1g are staggered along a normal direction L of the encapsulation structure 3.

In some embodiments, at the at least part of the smooth curved section of the encapsulation structure 3, the plurality of queues are numbered in sequence according to the normal direction L of the at least part of the smooth curved section, groove clusters 1g in odd-numbered ones of the queues are substantially aligned along the normal direction L of the encapsulation structure 3, groove clusters 1g in even-numbered ones of the queues are substantially aligned along the normal direction L of the encapsulation structure 3.

In some embodiments, in the same queue of the plurality of queues, a standard deviation of a distance between geometric centers of adjacent groove clusters 1g is within 10%. A standard deviation of the distance between the geometric centers of adjacent groove clusters 1g in any one of the queues and the distance between the geometric centers of adjacent groove clusters 1g in another one of the queues is within 10%.

In some embodiments, an opening of the groove 1f is formed in a shape of a rectangle, a circle, or a regular polygon.

In some embodiments, a surface of the groove 1f is formed by an insulating material (e.g., by an insulating layer 12).

In some embodiments, the display substrate 1 includes an electrically conductive layer 13. The electrically conductive layer 13 is provided with a plurality of opening regions (i.e., first openings H1). The insulating material (insulating layer 12) fills the opening region of the electrically conductive layer 13. The groove clusters 1g are provided in one-to-one correspondence with the opening regions of the electrically conductive layer 13. The groove 1f in the groove cluster 1g extends into a corresponding one of the opening regions of the electrically conductive layer 13.

The inventor of the present disclosure performed a whole machine drop test on a display device made of the display panel shown in FIG. 4b, and found that the stress is relatively concentrated at the corner positions of the rectangular first opening H1 and second opening H2, and that the risk of fracture at these positions is high.

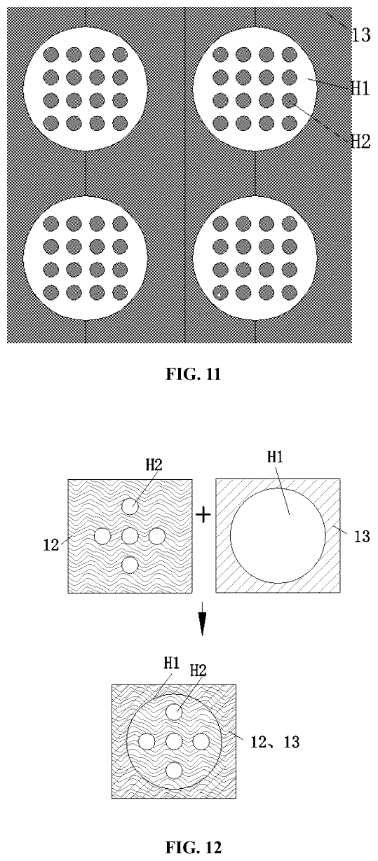

Referring to FIGS. 10, 11, and 12 and in combination with FIGS. 1, 2, 3, and 9, in a display panel of some other embodiments of the present disclosure, at any position of a boundary of an orthogonal projection of at least one of the first openings H1 on a reference plane, an angle between a left tangent line and a right tangent line is greater than 90°, and/or at any position of a boundary of an orthogonal projection of at least one second opening H2 on the reference plane, an angle between a left tangent line and a right tangent line is greater than 90°. The reference plane is a plane where the display substrate is located.

There is no right angles or acute angles at the boundary of the first opening H1 and at the boundary of the second opening H2, and the transition is relatively smooth, which helps the stress to be distributed more dispersed at the boundary of the first opening H1 and at the boundary of the second opening H2, thereby reducing the risk of structural fracture at the first opening H1 or the second opening H2, and facilitating to improve the structural stability of the display substrate.

Referring to FIG. 10, at least one of the first openings H1 is in a shape of a polygon, and vertex angles of the polygon are all obtuse angles. At the vertex angles of the polygon, an angle between a left tangent line and a right tangent line is an obtuse angle. At the rest positions of the polygon, an angle between a left tangent line and a right tangent line is 180°. The opening shape of the first opening H1 is, for example, a regular pentagon, a regular hexagon, etc.

Referring to FIG. 11, the opening shape of at least one of the first opening H1 is a closed smooth curve. The smooth curve is differentiable everywhere, and an angle between a left tangent line and a right tangent line at any position of the smooth curve is 180°.

The closed smooth curve is, for example, a circle or an ellipse.

In some embodiments, the opening shape of at least one of the first openings H1 is in a shape of a polygon with tips chamfered to round corners. At a junction point of the rounded corner section and the straight line section, an angle between a left tangent line and a right tangent line is an obtuse angle.

Referring to FIG. 9, at least one second opening H2 is in a shape of a polygon, and vertex angles of the polygon are all obtuse angles. At the vertex angles of the polygon, an angle between a left tangent line and a right tangent line is an obtuse angle. At the rest positions of the polygon, an angle between a left tangent line and a right tangent line is 180°. The opening shape of the second opening H2 is, for example, a regular pentagon, a regular hexagon, etc.

Referring to FIG. 10, the opening shape of at least one second opening H2 is a closed smooth curve. The smooth curve is differentiable everywhere, and an angle between a left tangent line and a right tangent line at any position of the smooth curve is 180°.

The closed smooth curve is, for example, a circle or an ellipse.

In some embodiments, the opening shape of at least one second opening H2 is in a shape of a polygon with tips chamfered to round corners. At a junction point of the rounded corner section and the straight line section, an angle between a left tangent line and a right tangent line is an obtuse angle.

The above opening shapes may be designed in combination. For example, in some other embodiments, the opening shape of the first opening H1 is a circle or an ellipse, and the shape of the second opening H2 therein may be a rectangle with tips chamfered to round corners, a circle, a regular octagon, or the like.

In the above design, the tips of the opening region (the first opening H1) of the electrically conductive layer 13, and the tips of the opening region (the second opening H2) of the insulating layer 12 are smoothly transitioned, avoiding over-concentration of the stress, thereby improving the reliability of the display device.

In some embodiments shown in FIG. 11, the diameter of the first opening H1 is in the range of 35 μm to 45 μm. The diameter of the second opening H2 is in the range of 5 μm to 7 μm. The gap size of the second opening H2 is in the range of 3 μm to 4 μm.

In an embodiment shown in FIG. 11, the diameter of the first opening H1 is 40 μm. The diameter of the second opening H2 is 6 μm. The size of the gap between adjacent second openings H2 is 3.5 μm.

Based on the same inventive concept, with continued reference to FIGS. 1 to 3 and 9 to 12, some embodiments of the present disclosure also provide a display panel including: a display substrate 1 and an encapsulation cover plate 2 disposed opposite to each other, a plurality of light-emitting elements provided on a surface of the display substrate 1 at a side of the display substrate 1 facing the encapsulation cover plate 2, and an encapsulation structure 3 provided between the display substrate 1 and the encapsulation cover plate 2 and surrounding the plurality of light-emitting elements.

The display substrate 1 is provided with a plurality of grooves 1f, in a region covered by the encapsulation structure 3, on a surface of the display substrate 1 at a side of the display substrate 1 facing the encapsulation cover plate 2. The encapsulation structure 3 fills the plurality of grooves 1f.

At any position of a boundary of an orthogonal projection of at least one of the grooves 1f on a reference plane, an angle between a left tangent line and a right tangent line is greater than 90°. The reference plane is a plane where the display substrate 1 is located.

The opening shape of the groove 1f is the opening shape of the second opening H2 on the insulating layer 12. The corner positions of the groove 1f are relatively smooth, and the stress at the corner positions is relatively small when the whole machine is subjected to the drop test. At the same time, the corner positions of the encapsulation structure 3 filled into the groove 1f are relatively smooth, and the internal stress of the encapsulation structure 3 is relatively small when the whole machine is subjected to the drop test. These contribute to improving the reliability of the display panel and the display device in which the display panel participates in the composition.

In some embodiments, an opening of at least one of the grooves 1f is in a shape of a polygon, and vertex angles of the polygon are all obtuse angles; and/or an opening of at least one of the grooves 1f is in a shape of a polygon with vertex angles chamfered to round corners.

In some embodiments, an opening of at least one of the grooves 1f is in a shape of a closed smooth curve.

In some embodiments, an opening of at least one of the grooves 1f is in a shape of a circle or an ellipse.

In some embodiments, the surface of the groove 1f is formed by an insulating material in a surrounding manner. For example, side walls of some grooves 1f are formed by the insulating material provided in the same layer as the interlayer dielectric layer and the insulating material provided in the same layer as the passivation layer. The bottom wall of the groove 1f is formed by the buffer layer.

In some embodiments, with continued reference to FIGS. 3 and 9 to 12, the display substrate 1 includes an electrically conductive layer 13. The electrically conductive layer 13 is provided with a plurality of opening regions. The insulating material fills the opening region of the electrically conductive layer 13. The groove extends into the opening region of the electrically conductive layer 13. The grooves 1f are gathered into a plurality of groove clusters 1g. The groove clusters 1g are provided in one-to-one correspondence with the opening regions of the electrically conductive layer 13. The groove 1f in the groove cluster 1g extends into a corresponding one of the opening regions of the electrically conductive layer 13.

The opening region of the electrically conductive layer 13 is the opening region of the first opening H1. The tips of the opening region of the electrically conductive layer 13 are smoothly transitioned, avoiding over-concentration of the stress, thereby improving the reliability of the display device.

In some embodiments, at any position of a boundary of an orthogonal projection of at least one of the opening regions on the reference plane, an angle between a left tangent line and a right tangent line is greater than 90°.

In some embodiments, at least one of the opening regions is in a shape of a polygon, and vertex angles of the polygon are all obtuse angles.

In some embodiments, at least one of the opening regions is in a shape of a polygon with vertex angles chamfered to round corners.

In some embodiments, at least one of the opening regions is in a shape of a closed smooth curve.

In some embodiments, at least one of the opening regions is in a shape of a circle or an ellipse.

Some embodiments of the present disclosure provide a display device including the aforementioned display panel.

The display device is a product or component having a display function. The display device is, for example, a display module, a head-mounted display device, a monitor, a mobile phone, a tablet computer, an intelligent interactive terminal, and the like.

Referring to FIG. 8, in some embodiments, the display device includes the aforementioned display panel, and further includes a polarizer 100 and a protection cover plate 200. The material of the protection cover plate 200 is, for example, glass. The display device further includes, for example, other structures such as a driving chip.

The embodiments in the present disclosure are described in a progressive manner, and the same and similar parts between the embodiments can be referred to each other. Descriptions of each embodiment focuses on the differences from other embodiments.

The scope of protection of the present disclosure is not limited to the above embodiments, and it is obvious that those skilled in the art can make various changes and deformations to the present disclosure without departing from the scope and spirit of the present disclosure. If these changes and deformations fall within the scope of the claims of the present disclosure and their technical equivalents, the intent of the present disclosure also encompasses these changes and deformations.

1. A display panel, comprising:
a display substrate, wherein the display substrate comprises a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, wherein the encapsulation structure is located between the display substrate and the encapsulation cover plate and surrounds the plurality of light-emitting elements, and the encapsulation structure is provided with a smooth curved section; wherein
a section of the display substrate covered by the encapsulation structure comprises a base, an electrically conductive layer and an insulating layer stacked in sequence along a direction pointed from the display substrate towards the encapsulation cover plate, the electrically conductive layer is provided with a plurality of first openings, the insulating layer fills the first opening, the insulating layer is provided with at least one second opening in a region where the first opening is located, and the encapsulation structure fills the second opening; and
at at least part of the smooth curved section of the encapsulation structure, the first openings are arranged in a plurality of queues along an orientation of the at least part of the smooth curved section, a center distance between two adjacent first openings in a same queue is substantially equal, and the center distance between the two adjacent first openings in any one of the queues is substantially equal to the center distance between the two adjacent first openings in another one of the queues.

2. The display panel according to claim 1, wherein at the at least part of the smooth curved section of the encapsulation structure, the first openings are substantially aligned along a normal direction of the encapsulation structure; and/or
at the at least part of the smooth curved section of the encapsulation structure, the first openings are staggered along a normal direction of the encapsulation structure.

3. (canceled)

4. The display panel according to claim 2, wherein at the at least part of the smooth curved section of the encapsulation structure, the plurality of queues are numbered in sequence according to the normal direction of the at least part of the smooth curved section, first openings in odd-numbered ones of the queues are substantially aligned along the normal direction of the encapsulation structure, first openings in even-numbered ones of the queues are substantially aligned along the normal direction of the encapsulation structure, and the first openings in the odd-numbered ones of the queues are staggered, along the normal direction of the encapsulation structure, with the first openings in the even-numbered ones of the queues; or
at the at least part of the smooth curved section of the encapsulation structure, first openings in any two of the queues are staggered along the normal direction of the at least part of the smooth curved section.

5. The display panel according to claim 1, wherein in the same queue of the plurality of queues, a standard deviation of the center distance between the adjacent first openings is within 10%; and a standard deviation of the center distance between the two adjacent first openings in any one of the queues and the center distance between the two adjacent first openings in another one of the queues is within 10%.

6. The display panel according to claim 1, wherein the first opening is formed in a shape of a rectangle, a circle, or a regular polygon; and/or
the second opening is formed in a shape of a rectangle, a circle, or a regular polygon.

7. (canceled)

8. The display panel according to claim 1, wherein the display panel comprises at least part of an arc edge, and the orientation of the at least part of the smooth curved section of the encapsulation structure is parallel to an orientation of the at least part of the arc edge of the display panel.

9. The display panel according to claim 1, wherein the light-emitting element comprises an organic light-emitting diode or a quantum dot light-emitting diode; or
a material of the electrically conductive layer is molybdenum.

10. The display panel according to claim 1, wherein a number of the second opening is multiple, and a gap is provided between the second opening and the first opening where the second opening is located; or
a number of the second opening is one, and the second opening coincides with the first opening where the second opening is located.

11. (canceled)

12. The display panel according to claim 1, wherein a distance between each of first openings in the same queue and an outer edge of the encapsulation structure is equal.

13. The display panel according to claim 6, wherein a number of edges of the regular polygon is not less than four.

14. (canceled)

15. A display panel, comprising:
a display substrate, comprising a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, wherein the encapsulation structure is located between the display substrate and the encapsulation cover plate, and surrounds the plurality of light-emitting elements; wherein
the display substrate is provided with a plurality of grooves, in a region covered by the encapsulation structure, on a surface of the display substrate at a side of the display substrate facing the encapsulation cover plate; and the encapsulation structure fills the plurality of grooves;
the display substrate further comprises a plurality of exposed electrical test pads, a test line electrically connected to the electrical test pad, and an electrostatic protection circuit electrically connected to the test line; and
the electrostatic protection circuit is connected to a second wiring located in a second wiring layer; at least a partial section of the test line is located in a first wiring layer; the first wiring layer and the second wiring layer are separated from each other by an insulating material; the second wiring and a first wiring are electrically connected, through a via passing through the insulating material, to each other at an overlapping position of the second wiring and the first wiring; and at least an orthogonal projection, on a plane where the display substrate is located, of the via connecting the first wiring and the second wiring is located within an orthogonal projection, on the plane where the display substrate is located, of the encapsulation structure.

16. The display panel according to claim 15, wherein the electrostatic protection circuit and the electrical test pads are located at a side of the encapsulation structure away from the display area.

17. The display panel according to claim 15, wherein an orthogonal projection, on the plane where the display substrate is located, of the electrostatic protection circuit, and the orthogonal projection, on the plane where the display substrate is located, of the via connecting the first wiring and the second wiring are located within the orthogonal projection, on the plane where the display substrate is located, of the encapsulation structure.

18. (canceled)

19. A display panel, comprising:
a display substrate, comprising a display area and a peripheral area;
a plurality of light-emitting elements, provided on a surface of the display substrate at a side of the display area;
an encapsulation cover plate, provided at a side of the light-emitting elements away from the display substrate; and
an encapsulation structure, provided on a surface of the display substrate at a side of the peripheral area, wherein the encapsulation structure is located between the display substrate and the encapsulation cover plate and surrounds the plurality of light-emitting elements, and the encapsulation structure is provided with a smooth curved section; wherein
the display substrate is provided with a plurality of grooves, in a region covered by the encapsulation structure, on a surface of the display substrate at a side of the display substrate facing the encapsulation cover plate; and the encapsulation structure fills the plurality of grooves; and
at a position where at least part of the smooth curved section of the encapsulation structure is located, the grooves are gathered into a plurality of groove clusters, the plurality of groove clusters are arranged in a plurality of queues along an orientation of the at least part of the smooth curved section, a center distance between two adjacent groove clusters in a same queue is substantially equal, and the center distance between the two adjacent groove clusters in any one of the queues is substantially equal to the center distance between the two adjacent groove clusters in another one of the queues.

20. The display panel according to claim 19, wherein at the at least part of the smooth curved section of the encapsulation structure, the groove clusters are substantially aligned along a normal direction of the encapsulation structure; or
at the at least part of the smooth curved section of the encapsulation structure, the groove clusters are staggered along a normal direction of the encapsulation structure.

21. (canceled)

22. The display panel according to claim 20, wherein at the at least part of the smooth curved section of the encapsulation structure, the plurality of queues are numbered in sequence according to the normal direction of the at least part of the smooth curved section, groove clusters in odd-numbered ones of the queues are substantially aligned along the normal direction of the encapsulation structure, groove clusters in even-numbered ones of the queues are substantially aligned along the normal direction of the encapsulation structure, and the groove clusters in the odd-numbered ones of the queues are staggered, along the normal direction of the encapsulation structure, with the groove clusters in the even-numbered ones of the queues; or
at the at least part of the smooth curved section of the encapsulation structure, groove clusters in any two of the queues are staggered along the normal direction of the at least part of the smooth curved section.

23. The display panel according to claim 19, wherein in the same queue of the plurality of queues, a standard deviation of a distance between geometric centers of the adjacent groove clusters is within 10%; and a standard deviation of the distance between the geometric centers of the adjacent groove clusters in any one of the queues and the distance between the geometric centers of the adjacent groove clusters in another one of the queues is within 10%; or
an opening of the groove is formed in a shape of a rectangle, a circle, or a regular polygon.

24. (canceled)

25. The display panel according to claim 19, wherein the groove is formed by an insulating material in a surrounding manner.

26. The display panel according to claim 25, wherein the display substrate comprises an electrically conductive layer, the electrically conductive layer is provided with a plurality of opening regions, the insulating material fills the opening region of the electrically conductive layer, the groove clusters are provided in one-to-one correspondence with the opening regions of the electrically conductive layer, and the groove in the groove cluster extends into a corresponding one of the opening regions of the electrically conductive layer.

27-35. (canceled)

36. A display device, comprising the display panel according to claim 1.
